(19) United States
(12) Patent Application Publication
(10) Pub. No.: US 2025/0322856 A1
(43) Pub. Date: Oct. 16, 2025

(54) RECEIVING DEVICE

(71) Applicant: Samsung Electronics Co., Ltd., Suwon-si (KR)

(72) Inventors: Hyunwoo Ahn, Suwon-si (KR); Tongsung Kim, Suwon-si (KR); Woojung Kim, Suwon-si (KR); Yoonji Park, Suwon-si (KR); Byungkwan Chun, Suwon-si (KR)

(21) Appl. No.: 18/829,589

(22) Filed: Sep. 10, 2024

(30) Foreign Application Priority Data
Apr. 11, 2024 (KR) 10-2024-0048546

(51) Int. Cl. G11C 7/10

(52) U.S. Cl. CPC G11C 7/1087; G11C 7/1084; G11C 7/1093

(57) ABSTRACT

A receiving device includes a data pin; a data buffer including a first input terminal configured to receive a data signal from the data pin, a second input terminal configured to receive a reference voltage, and an output terminal configured to output a comparison result between the data signal and the reference voltage as an output signal, a driver electrically connected between the data pin and the first input terminal, a reference voltage control circuit configured to output the reference voltage having a voltage corresponding to a reference voltage code to the second input terminal, and an adjustment circuit configured to apply an intermediate voltage of the data signal to the first input terminal using the driver, and configured to adjust the reference voltage code such that a voltage of the output signal reaches a target state.

### CROSS-REFERENCE TO RELATED APPLICATION(S)

This application claims benefit of priority to Korean Patent Application No. 10-2024-0048546 filed on Apr. 11, 2024 in the Korean Intellectual Property Office, the disclosure of which is incorporated herein by reference in its entirety.

### BACKGROUND

The present inventive concept relates to a receiving device receiving a data signal.

A receiving device may have a plurality of data receivers. Some of the data receivers may output a logic level corresponding to a data signal according to a comparison result between the data signal and a reference voltage. When the data receivers have an offset due to a process error, an effective window margin in which the comparison result between the data signal and the reference voltage has an accurate value may decrease.

A receiving device capable of calibrating the offset of the data receivers is required such that the data receivers may have an optimal effective window margin for the data signal.

### SUMMARY

Embodiments of the present inventive concept is to provide a receiving device capable of directly calibrating an offset in data receivers without external control.

Embodiments of the present inventive concept is to provide a receiving device capable of calibrating an offset in data receivers without weighting load on output terminals of the data receivers.

Embodiments of the present inventive concept is to provide a receiving device capable of calibrating an offset regardless of a conductivity type of semiconductor elements included in data receivers.

According to embodiments of the present inventive concept, a receiving device includes a data pin, a data buffer including a first input terminal configured to receive a data signal from the data pin, a second input terminal configured to receive a reference voltage, and an output terminal configured to output a comparison result between the data signal and the reference voltage as an output signal, a driver electrically connected between the data pin and the first input terminal, a reference voltage control circuit configured to output the reference voltage to the second input terminal, the reference voltage corresponds to a reference voltage code, and an adjustment circuit configured to apply an intermediate voltage of the data signal to the first input terminal using the driver, and configured to adjust the reference voltage code such that a voltage of the output signal reaches a target state.

According to embodiments of the present inventive concept, a receiving device includes a plurality of data pins, a plurality of data receivers each including a data buffer that includes an input terminal configured to receive a respective data signal of a plurality of data signals from a respective data pin among the plurality of data pins, and configured to output a comparison result between the data signal and a reference voltage as an output signal, a driver electrically connected between the respective data pin and the respective input terminal, and an individual calibration circuit configured to adjust the reference voltage such that a voltage of the output signal reaches a target state when an estimated intermediate voltage of the data signal is applied to the input terminal, and a group calibration circuit configured to adjust respective reference voltages of each of the plurality of data receivers, based on respective ones of a plurality of data signals input from respective ones of the plurality of data pins.

According to embodiments of the present inventive concept, a receiving device includes a data pin, a data buffer including a first input terminal configured to receive a data signal from the data pin, a second input terminal configured to receive a reference voltage, and an output terminal configured to output a comparison result between the data signal and the reference voltage as an output signal, and a reference voltage calibration circuit configured to apply an intermediate voltage of the data signal to the first input terminal, configured to initialize the reference voltage that is applied to the second input terminal, and configured to repeatedly perform adjusting the voltage of the reference voltage until the output signal generated by comparing the intermediate voltage and the voltage of the reference voltage reaches a target state.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a block diagram illustrating a system including a transmitting device and a receiving device.

FIG. 2 illustrates an eye diagram of a data signal.

FIGS. 3A and 3B are circuit diagrams illustrating data buffers.

FIG. 4 is a block diagram illustrating a data receiver according to some embodiments.

FIG. 5 is a view illustrating a method of calibrating process errors using a data receiver according to some embodiments.

FIG. 6 is a flowchart illustrating a method of calibrating a reference voltage according to some embodiments.

FIGS. 7A and 7B are graphs illustrating voltage levels of signals while a reference voltage is calibrated according to some embodiments.

FIGS. 8A and 8B are views illustrating a method of forming an intermediate level of a data signal in a data receiver.

FIG. 9 is a view illustrating a receiving device according to some embodiments.

FIG. 10 is a flowchart illustrating a method of calibrating a reference voltage according to some embodiments.

FIG. 11 is a graph illustrating voltage levels of signals while a reference voltage is calibrated according to some embodiments.

FIG. 12 is a view illustrating a memory device as an example of a receiving device according to some embodiments.

### DETAILED DESCRIPTION

Hereinafter, preferred embodiments of the present inventive concept will be described with reference to the attached drawings.

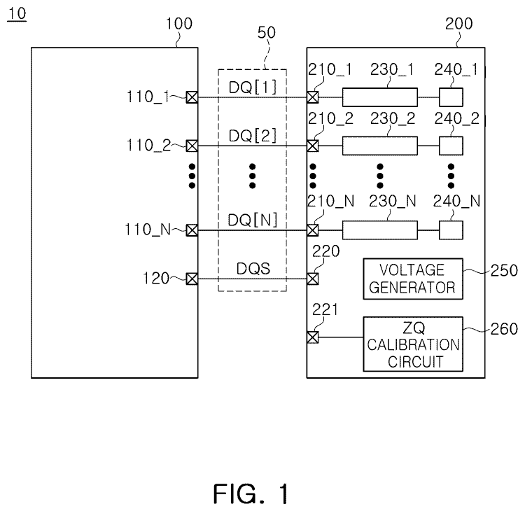

FIG. 1 is a block diagram illustrating a system including a transmitting device and a receiving device.

A system 10 may include a transmitting device 100, a receiving device 200, and a communication bus 50. The transmitting device 100 and the receiving device 200 may communicate with each other through the communication bus 50. The transmitting device 100 and the receiving device 200 may transmit and receive signals, respectively, but one may be referred to as the transmitting device 100 and the other may be referred to as the receiving device 200. For example, the system 10 may be a memory system, the receiving device 200 may be a memory device, and the transmitting device 100 may be a memory controller controlling the memory device.

The transmitting device 100 may be implemented as an integrated circuit, a system on chip (SoC), an application processor (AP), a mobile AP, a chipset, or a set of chips. The transmitting device 100 may include a random access memory (RAM), a central processing unit (CPU), a graphics processing unit (GPU), a neural processing unit (NPU), or a modem.

The receiving device 200 may be implemented as a volatile memory device or a non-volatile memory device. The volatile memory device may include at least one of a random access memory (RAM), a dynamic RAM (DRAM), a static RAM (SRAM), or a low power double data rate (LPDDR) DRAM, and the non-volatile memory device may include at least one of an electrically erasable programmable read-only memory (EPROM), a NOR flash memory, a NAND flash memory, a magnetoresistive random access memory (MRAM), a spin transfer torque (STT)-MRAM, a ferroelectric RAM (FeRAM), a phase change RAM (PRAM), a resistive RAM (RRAM), a nanotube RRAM, a polymer RAM (PoRAM)), a nano floating gate memory (NFGM), a holographic memory, a molecular electronics memory device, or an insulator resistance change memory.

The communication bus 50 may include a plurality of data lines for transmitting data signals DQ[1] to DQ[N]. Additionally, the communication bus 50 may further include one or more clock lines for transmitting a clock signal, for example, a data strobe signal DQS. The data signals DQ[1] to DQ[N] may be output from the transmitting device 100 in synchronization with the data strobe signal DQS, and may be sampled using the data strobe signal DQS by the receiving device 200.

The transmitting device 100 may include a plurality of first data pins 110 (110_1 to 110_N) for outputting the data signals DQ[1] to DQ[N], and one or more first clock pin 120 for outputting the data strobe signal DQS. Additionally, the receiving device 200 may include a plurality of second data pins 210 (210_1 to 210_N) for receiving the data signals DQ[1] to DQ[N], and one or more second clock pins 220 for receiving the data strobe signal DQS.

In some embodiments, the plurality of first data pins 110 and the first clock pin 120 may receive the data signals DQ[1] to DQ[N] and the data strobe signal DQS, respectively, and the plurality of second data pins 210 and the second clock pin 220 may output the data signals DQ[1] to DQ[N] and the data strobe signal DQS, respectively.

The receiving device 200 may further include a plurality of data receivers 230 (230_1 to 230_N), a plurality of sampling circuits 240 (240_1 to 240_N), a voltage generator 250, a ZQ pin 221, and a ZQ calibration circuit 260. Each of the plurality of data receivers 230 may be connected to one of the second data pins 210, and each of the plurality of sampling circuits 240 may be connected to one of the plurality of data receivers 230. As used herein, two elements that are described as being “connected” may be electrically connected and/or physically connected.

Each of the plurality of data receivers 230 may compare a data signal received from any one of the plurality of second data pins 210 with a reference voltage Vref, and may output a logic signal according to a comparison result therefrom. Additionally, each of the plurality of sampling circuits 240 may be synchronized to a clock signal, to sample the logic signal received from the data receiver 230.

The voltage generator 250 may generate voltage signals necessary for an operation of the receiving device 200. For example, the voltage generator 250 may generate the reference voltage Vref to be input to the plurality of data receivers 230.

The ZQ calibration circuit 260 may perform ZQ calibration to adjust driving ability of a driver connected to the plurality of second data pins 210, and integrity of data signals input and output from the plurality of second data pins 210 may be improved. The ZQ calibration circuit 260 may perform ZQ calibration using the ZQ pin 221. ZQ calibration may be related to the termination of the communication bus. Termination may be important for high-speed digital communication to prevent signal reflections and ensure data is transferred accurately. ZQ calibration may involve measuring the impedance of termination resistors located at the receiving device 200 and adjusting to match the impedance value to help ensure that signals are properly terminated and reflected signals do not interfere with data transmission.

In the receiving device 200, a logical value of the data signal may be determined based on the reference voltage Vref. For example, even though the transmitting device 100 has transmitted a data signal corresponding to a logic high value, when a level of a data signal received by the receiving device 200 is lower than the reference voltage Vref, the received data signal may be determined as a logic low value.

To improve accuracy of the logic signal output from the plurality of data receivers 230, the receiving device 200 may calibrate the reference voltage Vref applied to the plurality of data receivers 230. The plurality of data receivers 230 may have an offset due to a process error, and a degree of the offset may be changed for each of the data receivers. When the receiving device 200 individually calibrates the offset of the plurality of data receivers 230, accuracy of logic signals corresponding to each of the data signals DQ[1] to DQ[N] will be further improved.

According to some embodiments, the receiving device 200 may calibrate the offset of the plurality of data receivers 230 by individually calibrating the reference voltage Vref applied to the plurality of data receivers 230.

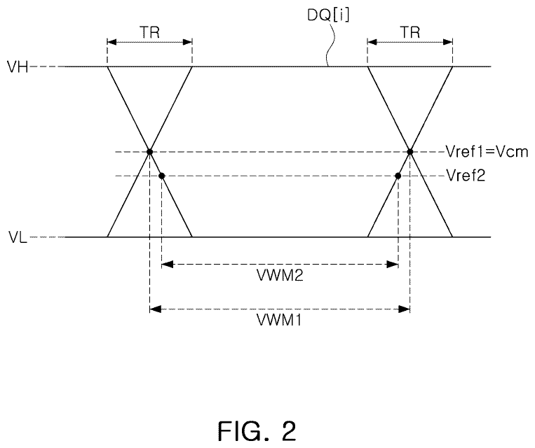

Hereinafter, before a receiving device according to some embodiments is described in detail, an effective data window according to the reference voltage Vref may be described with reference to FIG. 2.

FIG. 2 illustrates an eye diagram of a data signal.

FIG. 2 illustrates an eye diagram for a data signal DQ[i]. The data signal DQ[i] may correspond to any of the data signals DQ[1] to DQ[N] described with reference to FIG. 1.

Referring to FIG. 2, a data signal DQ[i] may include a logic high level VH and a logic low level VL. Additionally, the data signal DQ[i] may have a level transition period TR in which a logic level changes.

Due to the level transition period TR, an effective window margin may be changed depending on a reference voltage. The effective window margin may be defined as a period during which a comparison result of the data signal DQ[i] may maintain a high level or a low level. For example, a width of the effective window margin may be determined, based on a position in which the eye diagram and a reference voltage level intersect. FIG. 2 illustrates a first effective window margin VWM1 according to a first reference voltage Vref1 and a second effective window margin VWM2 according to a second reference voltage Vref2, respectively.

A data receiver may include a data buffer receiving the data signal DQ[i] and the reference voltage and comparing the data signal DQ[i] and the reference voltage to output a logic signal. In an ideal data receiver, the effective window margin would be widest when the reference voltage may be equal to an intermediate level Vcm of the data signal DQ[i]. An actual data receiver may have an offset due to a process error between a receiving portion of the data signal DQ[i] and a receiving portion of the reference voltage.

When there is an offset in the data receiver, the reference voltage at which the effective window margin is widest may not necessarily match the intermediate level Vcm. Also, when the receiving device has a plurality of data receivers having different offsets, reference voltages that may be the widest effective window margin in each of the plurality of data receivers may be different.

According to some embodiments, the receiving device may control a reference voltage such that the data receiver has a reference voltage that may widen the effective window margin, despite the offset of the data receiver. When the receiving device includes a plurality of receiving devices, the receiving device may individually control the reference voltage for the plurality of receiving devices.

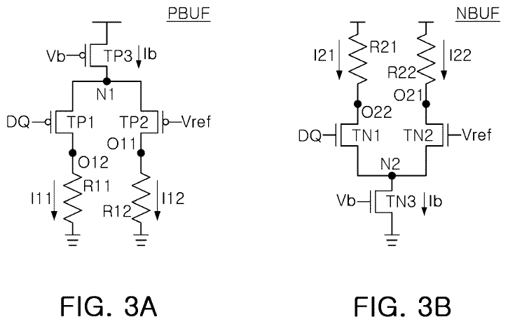

Hereinafter, the offset of the data receiver may be explained in detail with reference to FIGS. 3A and 3B.

FIGS. 3A and 3B are circuit diagrams illustrating data buffers.

FIG. 3A illustrates an example of a first data buffer PBUF, and FIG. 3B illustrates an example of a second data buffer NBUF.

Referring to FIG. 3A, a first data buffer PBUF may be a P-type data buffer. The first data buffer PBUF may include a structure similar to a differential amplifier. The first data buffer PBUF may receive a data signal DQ and a reference voltage Vref, may compare a level of the data signal DQ and a level of the reference voltage Vref, and may output a signal in which a comparison result therefrom is amplified, as an output signal.

For example, when the level of the data signal DQ is higher than the level of the reference voltage Vref, a high level signal may be output, and when the level of the data signal DQ is lower than the level of the reference voltage Vref, a low level signal may be output. For example, a high level may be a power level VCCQ and a low level may be a ground level.

The first data buffer PBUF may include a plurality of PMOS transistors TP1, TP2, and TP3. The data signal DQ may be applied to a gate of a first transistor TP1, a source thereof may be connected to a first node N1, and a drain thereof may be connected to a second output terminal O12. A first resistor R11 may be connected between the second output terminal O12 and a ground.

The reference voltage Vref may be applied to a gate of a second transistor TP2, a source thereof may be connected to the first node N1, and a drain thereof may be connected to a first output terminal O11. A second resistor R12 may be connected between the first output terminal O11 and a ground. The first resistor R11 and the second resistor R12 may have the same resistance value.

A third transistor TP3 may be connected between the first node N1 and a power source. The third transistor TP3 may provide a bias current Ib according to a bias voltage Vb applied to a gate thereof.

When the level of the data signal DQ is higher than the level of the reference voltage Vref, a level of a second current I12 determined by the second transistor TP2 may be higher than a level of a first current I11 determined by the first transistor TP1. Due to a voltage drop in the first resistor R11 and the second resistor R12, a voltage level of the first output terminal O11 may be higher than a voltage level of the second output terminal O12.

When the level of the data signal DQ is lower than the level of the reference voltage Vref, the level of the second current I12 may be lower than the level of the first current I11, and the voltage level of the first output terminal O11 may be lower than the voltage level of the second output terminal O12.

Although omitted in FIG. 3A, the first data buffer PBUF may further include an operational transconductance amplifier (OTA) circuit amplifying and outputting a difference between the voltage level of the first output terminal 011 and the voltage level of the second output terminal O12. The OTA circuit may output an output signal having a power level, for example, VCCQ, when the voltage level of the first output terminal O11 is higher than the voltage level of the second output terminal O12, and may output an output signal having a ground level, when the voltage level of the first output terminal O11 is lower than the voltage level of the second output terminal O12.

Referring to FIG. 3B, a second data buffer NBUF may be an N-type data buffer. The second data buffer NBUF may have a structure complementary to the first data buffer PBUF. Specifically, the second data buffer NBUF may include a plurality of NMOS transistors TN1, TN2, and TN3. A data signal DQ may be applied to a gate of a first transistor TN1, a source thereof may be connected to a second node N2, and a drain thereof may be connected to a second output terminal O22. A first resistor R21 may be connected between the second output terminal O22 and a power source.

A reference voltage Vref may be applied to a gate of a second transistor TN2, a source thereof may be connected to the second node N2, and a drain thereof may be connected to a first output terminal O21. A second resistor R22 may be connected between the first output terminal O21 and a power source. The second resistor R22 may have the same resistance value as the first resistor R21.

A third transistor TN3 may be connected between the second node N2 and a ground. The third transistor TN3 may provide a bias current Ib according to a bias voltage Vb applied to a gate thereof.

Although omitted in FIG. 3B, the second data buffer NBUF may further include an OTA circuit amplifying and outputting a difference between a voltage level of the first output terminal O21 and a voltage level of the second output terminal O22.

When a level of the data signal DQ is higher than a level of the reference voltage Vref, a level of a first current I21 determined by the first transistor TNI may be higher than a level of a second current I22 determined by the second transistor TN2. Due to a voltage drop in the first resistor R21 and the second resistor R22, a voltage level of the first output terminal O21 may be higher than a voltage level of the second output terminal O22. As a result, the second data buffer NBUF may output an output signal having a power level.

When the level of the data signal DQ is lower than the level of the reference voltage Vref, the level of the first current I21 may be lower than the level of the second current I22. The voltage level of the first output terminal O21 may be lower than the voltage level of the second output terminal O22, and the second data buffer NBUF may output an output signal having a ground level.

In an example of the first data buffer PBUF, in an ideal case, a size of the first transistor TP1 may be the same as a size of the second transistor TP2. In an ideal case, when the level of the data signal DQ is the same as the level of the reference voltage Vref, a current level of the first current I11 may be the same as a current level of the second current I12. A size of a transistor may be defined as a ratio of a width of a channel and a length of the channel.

The first data buffer PBUF may have a difference in the size of the first transistor TP1 and the size of the second transistor TP2 due to a process error. When there is an offset in the first data buffer PBUF, an amount of current flowing through the first transistor TP1 and the second transistor TP2 may be changed, even when the voltage level of the data signal DQ and the voltage level of the reference voltage Vref are the same.

For example, when the size of the second transistor TP2 is larger than the size of the first transistor TP1, and the voltage level of the data signal DQ and the voltage level of the reference voltage Vref are the same, the current level of the second current I12 may be greater than the current level of the first current I11. When the current level of the second current I12 is greater than the current level of the first current I11, the first data buffer PBUF may output an output signal having a power level. For example, even though the voltage level of the data signal DQ and the voltage level of the reference voltage Vref are the same, the first data buffer PBUF may output the same output signal as a case in which the voltage level of the data signal DQ is higher than the voltage level of the reference voltage Vref.

As a result, when there is an offset in the first data buffer PBUF and it is determined that the voltage level of the reference voltage Vref is equal to a central voltage level of the data signal DQ, the first data buffer PBUF may not have a maximum effective window margin.

Likewise, in the second data buffer NBUF, when there is a difference between a size of the first transistor TN1 and a size of the second transistor TN2, and it is determined that the voltage level of the reference voltage Vref is equal to a central voltage level of the data signal DQ, the second data buffer NBUF may not have a maximum effective window margin.

To calibrate the offset of the first data buffer PBUF, a method of selectively enabling spare transistors by connecting the spare transistors to each of the first and second output terminals O11 and O12, and comparing the sizes of the first and second transistors TP1 and TP2 may be considered. In the method, the sizes of the first and second transistors TP1 and TP2 may be compared in a state in which the gates of the first and second transistors TP1 and TP2 are connected to the ground, respectively.

When load on the output terminal increases due to the enabling of the spare transistors, a bandwidth of the output signal may decrease. When the gates of the first and second transistors TN1 and TN2, each of which may be an NMOS transistor, may be connected to the ground, the first and second transistors TN1 and TN2 may be turned off. Therefore, it may be difficult to determine the offset of the second data buffer NBUF and calibrate the offset using the above method.

According to some embodiments, each of the data receivers included in the receiving device may calibrate the offset of the data buffer by adjusting the voltage level of the reference voltage Vref, instead of adjusting the load of the output terminal. Specifically, each of the data receivers may adjust the voltage level of the reference voltage Vref such that, when the central level of the data signal DQ is applied to the first transistor to which the data signal DQ is applied, currents flowing through the first transistor and the second transistor have the same current level.

According to some embodiments, since the load may not be added to the output portion of the data buffer, a decrease in bandwidth of the output signal may be prevented. Additionally, the method of adjusting the voltage level of the reference voltage Vref, based on the intermediate voltage, may be used to calibrate the offset of the first data buffer PBUF, which may be a P-type data buffer, and may also be used to calibrate the offset of the second data buffer NBUF, which may be an N-type data buffer.

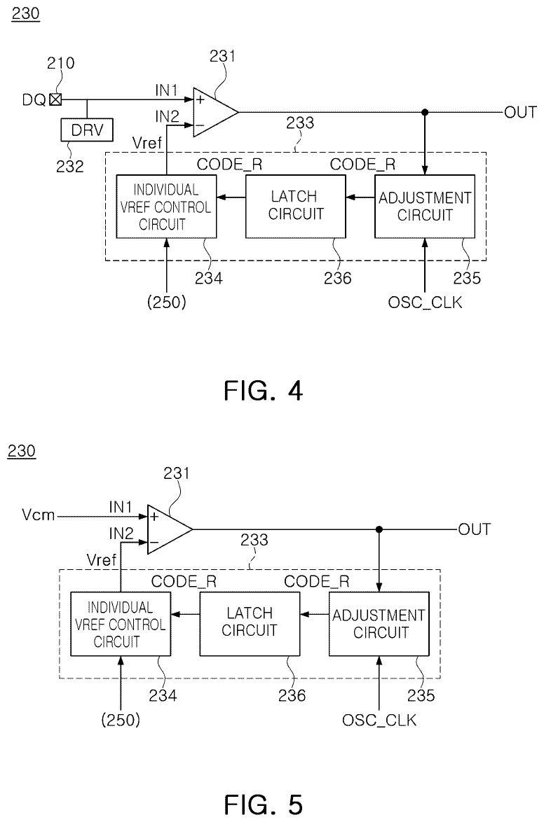

Hereinafter, a data receiver, and a method for calibrating a reference voltage according to some embodiments will be described in detail with reference to FIGS. 4 to 8.

FIG. 4 is a block diagram illustrating a data receiver according to some embodiments.

A data receiver 230 of FIG. 4 may correspond to any of the plurality of data receivers 230 (230_1 to 230_N) described with reference to FIG. 1.

The data receiver 230 may include a data buffer 231, a driver 232, and a reference voltage calibration circuit 233.

The data buffer 231 may include a first input terminal IN1, a second input terminal IN2, and an output terminal. A data signal DQ received from a data pin 210 may be input to the first input terminal IN1, and a reference voltage Vref may be input to the second input terminal IN2. The data buffer 231 may compare a voltage level of a signal input to the first input terminal IN1 and a voltage level of a signal input to the second input terminal IN2, and may output an output signal OUT to the output terminal according to a comparison result therefrom.

The data buffer 231 may correspond to the first data buffer PBUF or the second data buffer NBUF described with reference to FIGS. 3A and 3B. A circuit structure of the data buffer 231 is not limited to a structure of the first data buffer PBUF or a structure of the second data buffer NBUF. The data buffer 231 may have a first transistor into which the data signal DQ is input, and a second transistor into which the reference voltage Vref is input, and may have one of various structures that may output a signal in which the comparison result of comparing the data signal DQ and the reference voltage Vref is amplified, as the output signal OUT.

The driver 232 may be connected to the data pin 210 to increase driving capability when the data pin 210 outputs a data signal to a transmitting device 100. For example, the driver 232 may include a pull-up driver for driving a voltage of the data pin 210 in a power level, and a pull-down driver for driving the voltage of the data pin 210 in a ground level. The pull-up driver may include a plurality of PMOS transistors, and the pull-down driver may include a plurality of NMOS transistors.

The reference voltage calibration circuit 233 may perform feedback control on the reference voltage Vref to calibrate the reference voltage Vref. The reference voltage calibration circuit 233 may include an individual reference voltage control circuit 234, an adjustment circuit 235, and a latch circuit 236.

The individual reference voltage control circuit 234 may receive a voltage signal from a voltage generator 250, as described with reference to FIG. 1, and may adjust a level of the voltage signal to correspond to a reference voltage code CODE_R externally input. Additionally, the individual reference voltage control circuit 234 may input a voltage having the adjusted level, as the reference voltage Vref, to the second input terminal IN2 of the data buffer 231.

The adjustment circuit 235 may adjust the reference voltage code CODE_R, based on a voltage level of the output signal OUT, to adjust the level of the reference voltage Vref. The adjustment circuit 235 may operate in synchronization with an internal clock signal OSC_CLK, but the present inventive concept is not limited thereto.

The latch circuit 236 may store the reference voltage code CODE_R output from the adjustment circuit 235, and may provide the stored reference voltage code CODE_R to the individual reference voltage control circuit 234. For example, while the receiving device 200 described with reference to FIG. 1 performs an initialization operation, the reference voltage calibration circuit 233 may adjust the reference voltage code CODE_R and may store the adjusted reference voltage code CODE_R in the latch circuit 236. When the initialization operation of the receiving device 200 is completed and a data transmission/reception operation is performed, the latch circuit 236 may provide the stored reference voltage code CODE_R to the individual reference voltage control circuit 234, to maintain a voltage level of the calibrated reference voltage Vref.

According to some embodiments, the reference voltage calibration circuit 233 may perform feedback control for the reference voltage Vref on the second input terminal IN2, in a state in which a voltage corresponding to the intermediate voltage level of the data signal DQ to the first input terminal IN1, to calibrate the reference voltage Vref.

FIG. 5 is a view illustrating a method of calibrating process errors using a data receiver according to some embodiments.

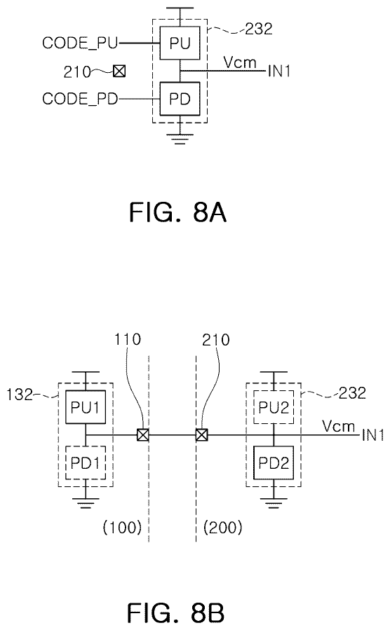

FIG. 5 illustrates a state in which a voltage having an intermediate level Vcm is applied to a first input terminal IN1 in a data receiver 230, as described with reference to FIG. 4. In some embodiments, when the voltage having the intermediate voltage level Vcm is applied to the first input terminal IN1, a data pin 210 may be floated. A method of forming the voltage having the intermediate voltage level Vcm in the first input terminal IN1 will be described hereinafter with reference to FIGS. 8A and 8B.

According to some embodiments, a reference voltage calibration circuit 233 may adjust a reference voltage code CODE_R such that an output signal OUT has a target state, in a state in which the voltage having the intermediate voltage level Vcm may be applied to the first input terminal IN1 and a reference voltage Vref may be applied to a second input terminal IN2.

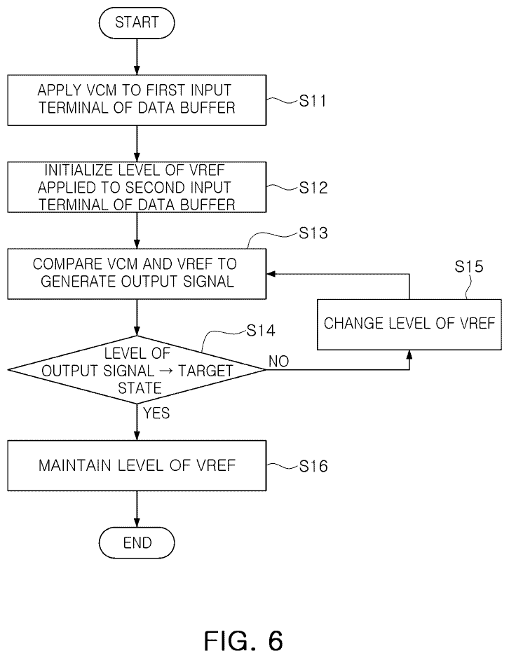

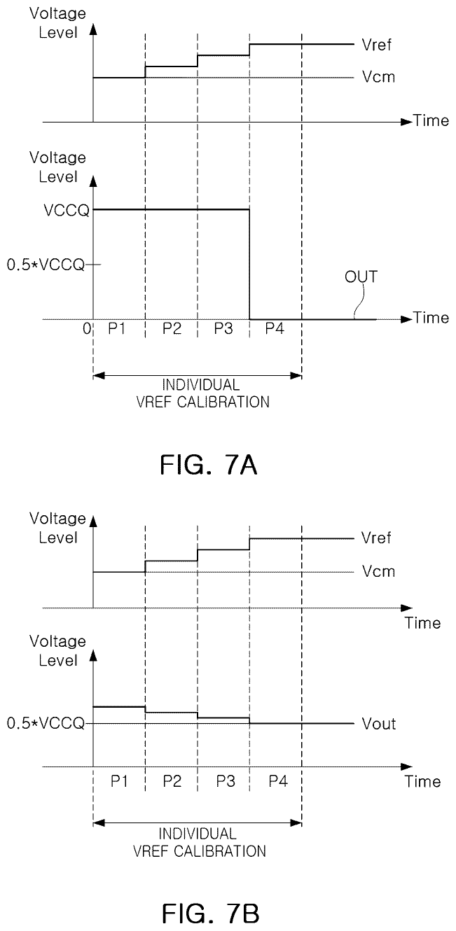

Hereinafter, a method for calibrating the reference voltage Vref of the data receiver 230 according to some embodiments will be described in detail with reference to FIGS. 6, 7A, and 7B.

FIG. 6 is a flowchart illustrating a method of calibrating a reference voltage according to some embodiments.

Referring to FIG. 6, a method of calibrating a reference voltage may include S11, S12, S13, S14, S15, and S16.

Referring to S11, a data receiver 230 may apply a voltage of an intermediate level Vcm to a first input terminal IN1 of a data buffer 231.

Referring to S12, the data receiver 230 may initialize a level of a reference voltage Vref applied to a second input terminal IN2 of the data buffer 231. Specifically, the data receiver 230 may initialize a reference voltage code CODE_R input to an individual reference voltage control circuit 234, to initialize the level of the reference voltage Vref.

In some embodiments, the data receiver 230 may initialize the voltage level of the reference voltage Vref such that the voltage level of the reference voltage Vref is the same as the intermediate voltage level Vcm. However, the present inventive concept is not limited thereto, and the voltage level of the reference voltage Vref may be initialized to an arbitrary level.

In S13, the data receiver 230 may compare the level of the intermediate voltage level Vcm and the reference voltage Vref to generate an output signal OUT. Specifically, when the intermediate voltage level Vcm and the reference voltage Vref are applied to the data buffer 231, the data buffer 231 may output the output signal OUT.

In S14, the data receiver 230 may determine whether a voltage level of the output signal OUT has reached a target state.

As explained with reference to FIGS. 3A and 3B, the voltage level of the output signal OUT may be determined by amplifying a difference between a voltage level of a first output terminal and a voltage level of a second output terminal. The voltage levels of the first and second output terminals may be determined, depending on a level of a first current flowing in a first transistor to which a data signal DQ is applied, and a voltage level of a second current flowing in a second transistor to which the reference voltage Vref is applied.

In some embodiments, the adjustment circuit 235 may detect a state in which the level of the output signal OUT toggles from a power level to a ground level, or from the ground level to the power level, as a target state. The state in which the level of the output signal OUT is toggled may be a state in which a relative magnitude of the level of the first current and a relative magnitude of the level of the second current are reversed, and a state in which a difference in magnitude between the current level of the first current and the current level of the second current is almost zero.

When the voltage level of the output signal OUT does not reach the target state (“No” in S14), the data receiver 230 may change the voltage level of the reference voltage Vref in S15. For example, an adjustment circuit 235 may increase or decrease the reference voltage code CODE_R, and may store the increased or decreased reference voltage code CODE_R in a latch circuit 236. The individual reference voltage control circuit 234 may input the reference voltage Vref, corresponding to the reference voltage code CODE_R stored in the latch circuit 236, to the second input terminal IN2.

The adjustment circuit 235 may control the voltage level of the reference voltage Vref in a manner in which the difference between the voltage level of the first output terminal and the voltage level of the second output terminal decreases. For example, when the output signal OUT has a power level, the adjustment circuit 235 may control the voltage level of the reference voltage Vref in a manner in which the voltage level of the first output terminal decreases and the voltage level of the second output terminal increases. When the output signal OUT has a ground level, the adjustment circuit 235 may control the level of the reference voltage Vref in a manner in which the voltage level of the first output terminal increases and the voltage level of the second output terminal decreases.

Specifically, the adjustment circuit 235 may increase the voltage level of the reference voltage Vref when the output signal OUT has a power level, and may decrease the voltage level of the reference voltage Vref when the output signal OUT has a ground level.

The data receiver 230 may repeatedly perform S13 to S15 until the voltage level of the output signal OUT reaches the target state.

When the voltage level of the output signal OUT reaches the target state (“YES” in S14), the data receiver 230 may maintain the voltage level of the reference voltage Vref in S16. For example, the data receiver 230 may maintain the reference voltage code CODE_R stored in the latch circuit 236. After calibration of the reference voltage Vref is completed, the individual reference voltage control circuit 234 may use the reference voltage code CODE_R stored in the latch circuit 236, to apply the calibrated reference voltage Vref to the second input terminal IN2.

FIGS. 7A and 7B are graphs illustrating voltage levels of signals while a reference voltage is calibrated according to some embodiments.

Specifically, FIGS. 7A and 7B illustrate a level of a reference voltage Vref, an intermediate voltage level Vcm, and a level of an output signal OUT, over time.

In an example of FIG. 7A, a voltage level of a reference voltage Vref may be initialized to have the same level as an intermediate voltage level Vcm in a first period P1. In the first period P1, a level of an output signal OUT may have a power level VCCQ.

For example, when a data buffer 231 is a first data buffer PBUF, as described with reference to FIG. 3A, and a size of a second transistor TP2 is greater than a size of a first transistor TP1, a current level of a second current flowing through the second transistor TP2 may be higher than a current level of a first current flowing through the first transistor TP1. Even though the voltage level of the reference voltage Vref is the same as the intermediate voltage level Vcm, the voltage level of the output signal OUT may be amplified to have the power level VCCQ due to an offset of the data buffer 231.

A data receiver 230 may repeatedly perform S13 to S15 described with reference to FIG. 6 from the first period PI to a fourth period P4, to execute calibration of the reference voltage Vref.

For example, when the data buffer 231 is the first data buffer PBUF as described with reference to FIG. 3A, and the voltage level of the output signal OUT has the power level VCCQ, the voltage level of the reference voltage Vref may increase to decrease the current level of the second current and increase the current level of the first current.

In the fourth period P4, the level of the output signal OUT may be toggled from the power level VCCQ to a ground level 0. For example, while executing calibration of the reference voltage Vref, a difference between the current level of the second current and the current level of the first current may gradually decrease, and then relative magnitudes of the current levels of the first and second currents may be reversed. At a moment at which the relative magnitudes of the current levels of the first and second currents are reversed, the difference between the current levels of the first and second currents may be minimal. Therefore, the data receiver 230 may complete the calibration of the reference voltage Vref in the fourth period P4.

FIG. 7A illustrates that an example in which a target state of the output signal is a state in which the output signal is toggled as an example. The present inventive concept is not limited thereto. For example, the target state of the output signal may be a state in which the output signal has a target level of medium between a power voltage and a ground voltage, i.e., 0.5*VCCQ.

The data buffer 231 described with reference to FIG. 5 may further include an amplifier linearly amplifying and outputting a difference between a voltage level of a first output terminal and a voltage level of a second output terminal as an analog output signal Vout, to calibrate the reference voltage Vref. For example, when the second output terminal has a maximum voltage level, the output signal Vout may have the power level VCCQ, and when the first output terminal has a maximum voltage level, the output signal Vout may have the ground level. When the voltage levels of the first output terminal and the second output terminal are the same, the output signal Vout may have a level of 0.5*VCCQ, which may be a medium between the power level and the ground level.

In an example of FIG. 7B, a voltage level of a reference voltage Vref may be initialized to have the same voltage level as an intermediate voltage level Vcm in a first period P1. In the first period P1, a voltage level of an output signal OUT may be greater than the medium level (0.5*VCCQ) between the power level and the ground level.

A data receiver 230 may increase the voltage level of the reference voltage Vref when the voltage level of the output signal OUT is greater than a target voltage level, and may decrease the voltage level of the reference voltage Vref when the voltage level of the output signal OUT is less than the target voltage level.

While the data receiver 230 repeatedly performs S13 to S15 described with reference to FIG. 6 from the first period P1 to a fourth period P4, the voltage level of the output signal OUT may gradually decrease, and the voltage level of the output signal OUT may reach the target voltage level in the fourth period P4. The data receiver 230 may complete calibration of the reference voltage Vref in the fourth period P4.

According to some embodiments, a plurality of data receivers 230 (230_1 to 230_N), as described with reference to FIG. 1, may include an individual reference voltage control circuit 234, and may individually calibrate the reference voltage Vref. A receiving device 200, as described with reference to FIG. 1, may individually calibrate an offset of each of the data receivers 230 to improve an effective window margin, respectively, for a plurality of data signals DQ[1] to DQ[N].

The data receiver 230 may internally calibrate the reference voltage Vref without relying on external control, including a transmitting device 100. For example, the data receiver 230 may form the intermediate voltage level Vcm in a first input terminal IN1 in a state in which a data signal DQ is not externally applied, and may use the intermediate voltage level Vcm to calibrate the reference voltage Vref.

FIGS. 8A and 8B are views illustrating a method of forming an intermediate voltage level of a data signal in a data receiver.

FIGS. 8A and 8B illustrate a circuit electrically connected to a first input terminal IN1 of a data receiver 230, as described with reference to FIGS. 4 and 5.

Referring to FIG. 8A, a data receiver 230 may electrically float a first input terminal IN1 and a data pin 210, to form an intermediate voltage level Vcm of a data signal DQ in the first input terminal IN1. A driver 232, as described with reference to FIG. 4, may be electrically connected to the first input terminal IN1. The driver 232 may include a pull-up driver PU connected between the first input terminal IN1 and a power source, and a pull-down driver PD connected between the first input terminal IN1 and a ground.

For example, the pull-up driver PU may include a plurality of PMOS transistors connected in parallel. Each of the plurality of PMOS transistors of the pull-up driver PU may be turned on when enabled, and may generate data of a logic high level at the data pin 210. As the number of PMOS transistors to be turned on increases, the number of resistors connected in parallel may increase. Therefore, as the number of PMOS transistors to be turned on increases, a resistance value of the pull-up driver PU may decrease and driving capability of the pull-up driver PU may increase.

Additionally, the pull-down driver PD may include a plurality of NMOS transistors connected in parallel. Each of the plurality of NMOS transistors of the pull-down driver PD may be turned on when enabled, and may generate data of a logic low level at the data pin 210. As the number of NMOS transistors to be turned on increases, the number of resistors connected in parallel may increase, a resistance value of the pull-down driver PD may decrease, and driving capability of the pull-down driver PD may increase.

The driving capabilities of the pull-up driver PU and pull-down driver PD may be determined by ZQ calibration of a receiving device 200. The ZQ calibration may include processes of generating a pull-up code CODE_PU and a pull-down code CODE_PD, determined according to a process-voltage-temperature (PVT) condition of the semiconductor elements of the receiving device 200 for impedance matching of the data pin 210. The pull-up code CODE_PU and the pull-down code CODE_PD may determine the number of transistors to be turned on in the pull-up driver PU and pull-down driver PD, respectively.

According to some embodiments, the driver 232 may input the pull-up code CODE_PU to the pull-up driver PU and the pull-down code CODE_PD to the pull-down driver PD, respectively, to determine a pull-up resistance value and a pull-down resistance value. Additionally, an adjustment circuit 235 may control to float the data pin 210 connected to the first input terminal IN1 and turn on the pull-up driver PU and the pull-down driver PD, to apply the intermediate voltage level Vcm of the data signal DQ to the first input terminal IN1.

According to some embodiments, the data receiver 230 may control the intermediate voltage level Vcm to be applied to the first input terminal IN1 without receiving the data signal DQ externally. The present inventive concept is not limited to a case in which the first input terminal IN1 is floating with the data pin 210.

Referring to FIG. 8B, a partial configuration of a transmitting device 100 and a partial configuration of a receiving device 200 of a system 10, as described with reference to FIG. 1, are illustrated.

The receiving device 200 may include a driver 232 connected to a data pin 210, similar to that described with reference to FIG. 8A, and the driver 232 may include a pull-up driver PU2 and a pull-down driver PD2. Likewise, the transmitting device 100 may include a driver 132 connected to a data pin 110, and the driver 132 may include a pull-up driver PU1 and a pull-down driver PD1.

In an example of FIG. 8B, the data pin 210 may not be floating, and may be connected to the driver 232 and a first input terminal IN1.

According to some embodiments, the receiving device 200 may be controlled to apply an intermediate voltage level Vcm to the first input terminal IN1 by using the pull-up drivers and the pull-down drivers of the first driver 132 and the second driver 232.

As a first example, when the first pull-up driver PU1 is turned on and the first pull-down driver PD1 is turned off, the data receiver 230 may be controlled to turn off the second pull-up driver PU2 and turn on the second pull-down driver PD2, to apply the intermediate level Vcm to the first input terminal IN1. As a second example, when the first pull-up driver PU1 is turned off and the first pull-down driver PD1 is turned on, the data receiver 230 may control to turn on the second pull-up driver PU2 and turn off the second pull-down driver PD2, to apply the intermediate voltage level Vcm to the first input terminal IN1.

According to some embodiments, it is possible to control the intermediate voltage level Vcm to be applied to the first input terminal IN1 without receiving a data signal externally. Therefore, the receiving device 200 may calibrate a voltage level of the reference voltage Vref without depending on control of the transmitting device 100.

The intermediate voltage level Vcm applied using the pull-up driver and the pull-down driver may have an error with an intermediate voltage level of a data signal DQ, which is actually received. The pull-up code and the pull-down code of the drivers respectively connected to a plurality of second data pins 210 (210_1 to 210_N), as described with reference to FIG. 1, may be collectively determined according to a ZQ calibration result of the receiving device 200. When there is an error in the ZQ calibration result, there may be an error in the intermediate voltage level Vcm determined by the pull-up driver PU and the pull-down driver PD. When the reference voltage Vref is calibrated based on the intermediate voltage level Vcm having the error, it may be difficult for the calibrated reference voltage Vref to have a maximum effective window margin.

According to some embodiments, after reference voltages Vref of a plurality of data receivers 230 of the receiving device 200 are individually calibrated, errors in the reference voltages Vref may be collectively calibrated based on data signals DQ[1] to DQ[N] received from a plurality of data pins 210.

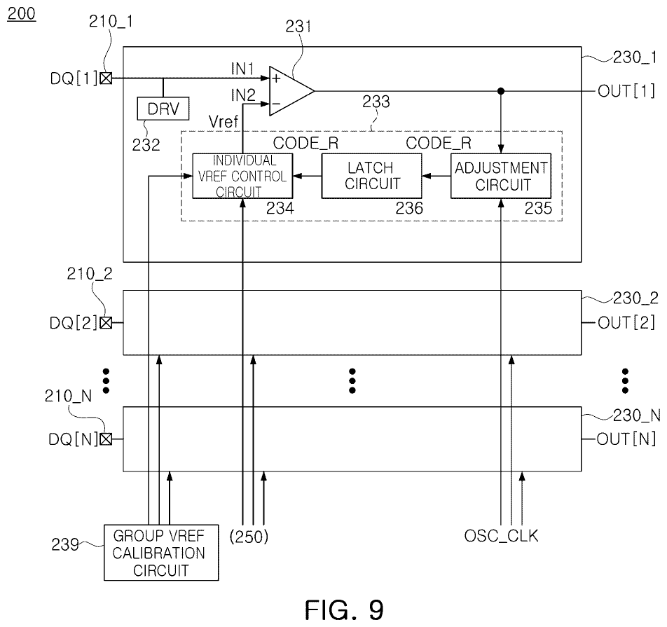

Hereinafter, a receiving device according to some embodiments will be described in detail with reference to FIGS. 9, 10, and 11.

FIG. 9 is a view illustrating a receiving device according to some embodiments.

As described with reference to FIG. 1, a receiving device 200 may include a plurality of second data pins 210 (210_1 to 210_N) receiving a plurality of data signals DQ[1] to DQ[N], and a plurality of data receivers 230 (230_1 to 230_N) connected to the plurality of second data pins 210 (210_1 to 210_N).

FIG. 9 illustrates a circuit structure of a first data receiver 230_1 among the plurality of data receivers 230. For example, the first data receiver 230_1 may have the same circuit structure as described with reference to FIG. 4. Additionally, a second data receiver 230_2 to an Nth data receiver 230_N may have the same circuit structure as the first data receiver 230_1.

Each of the plurality of data receivers 230 may individually compensate for a reference voltage received from a voltage generator 250 using a reference voltage calibration circuit 233, to compensate for an offset of a data buffer 231.

According to some embodiments, the receiving device 200 may further include a group reference voltage calibration circuit 239. The group reference voltage calibration circuit 239 may provide a control signal to an individual reference voltage control circuit 234 of each of the plurality of data receivers 230.

For example, the group reference voltage calibration circuit 239 may increase or decrease levels of reference voltages Vref output from the individual reference voltage control circuits 234, to have the same degree. The reference voltage calibration circuit 233 may be referred to as an individual calibration circuit, and the group reference voltage calibration circuit 239 may be referred to as a group calibration circuit.

A pull-up code and a pull-down code, determined according to a ZQ calibration result of the receiving device 200, may be uniformly and respectively applied to drivers 232 of the plurality of data receivers 230. Therefore, when each of the plurality of data receivers 230 individually calibrate the voltage level of the reference voltage Vref, the reference voltages Vref may include the same error component.

The error component may be corrected by collectively calibrating the reference voltages Vref using the data signals DQ[1] to DQ[N] received from each of the plurality of data receivers 230 by the group reference voltage calibration circuit 239.

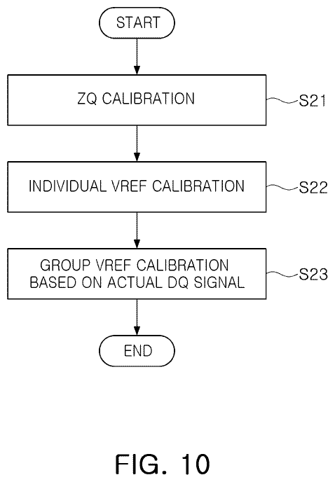

FIG. 10 is a flowchart illustrating a method of calibrating a reference voltage according to some embodiments.

Referring to FIG. 10, a method of calibrating a reference voltage Vref may include S21, S22, and S23. S21, S22, and S23 may be performed during an initialization process of a receiving device 200.

In S21, a receiving device 200 may perform ZQ calibration. The ZQ calibration may be performed using a ZQ pin 221, as described with reference to FIG. 1. For example, the ZQ pin 221 may be connected to a resistor in the receiving device 200. The receiving device 200 may adjust a pull-up code and a pull-down code for impedance matching while the resistor is connected to the ZQ pin 221. When the adjustment of the pull-up code and pull-down code is completed, the receiving device 200 may input the pull-up code and the pull-down code to a driver 232 of a plurality of data receivers 230.

In S22, each of the plurality of data receivers 230 may individually perform calibration of a reference voltage Vref. A method in which each of the plurality of data receivers 230 performs the calibration of the reference voltage Vref may include S11, S12, S13, S14, S15, and S16 of FIG. 6.

According to some embodiments, each of the plurality of data receivers 230 may float a data pin, and may simultaneously turn on a pull-up driver PU and a pull-down driver PD, to apply an intermediate voltage level Vcm of a data signal DQ to a first input terminal IN1 of a data buffer 231. To determine the intermediate voltage level Vcm of the data signal DQ, S21 may be performed before S22.

In some embodiments, since each of the plurality of data receivers 230 may have a reference voltage calibration circuit, an operation of S22 may be performed simultaneously with other operations for initializing the receiving device 200. For example, an operation of training a clock duty cycle of the receiving device 200 may be performed, independently of the calibration of the reference voltage Vref of the data signal DQ. Therefore, to reduce a time for initialization of the receiving device 200, the operation of S22 may be performed simultaneously with the operation of training the clock duty cycle.

In S23, a group reference voltage calibration circuit 239 may calibrate the reference voltage Vref of each of the plurality of data receivers 230.

For example, the group reference voltage calibration circuit 239 may add or remove a common value to reference voltage codes input to a reference voltage control circuit 234 of each of the plurality of data receivers 230, to calibrate the reference voltage Vref. Data pins 210 floating in S22 may be electrically connected to the plurality of data receivers 230 in S23. The group reference voltage calibration circuit 239 may use data signals DQ[1] to DQ[N] received from the data pins 210 to adjust the data signals DQ[1] to DQ[N], to find a common value that may maximize an effective window margin. Additionally, the common value may be applied to the reference voltage Vref of each of the plurality of data receivers 230 to collectively calibrate commonly included error components.

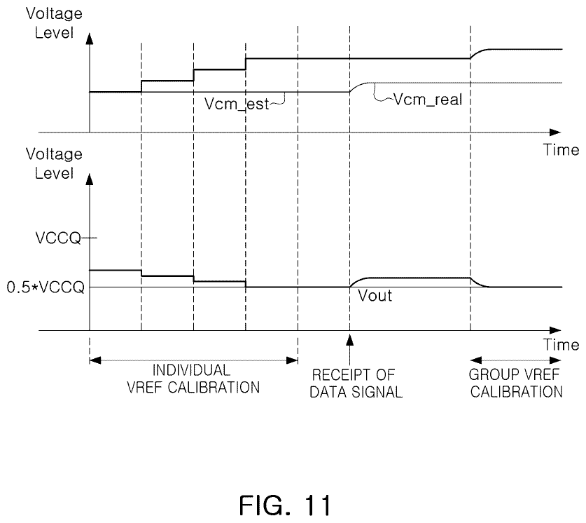

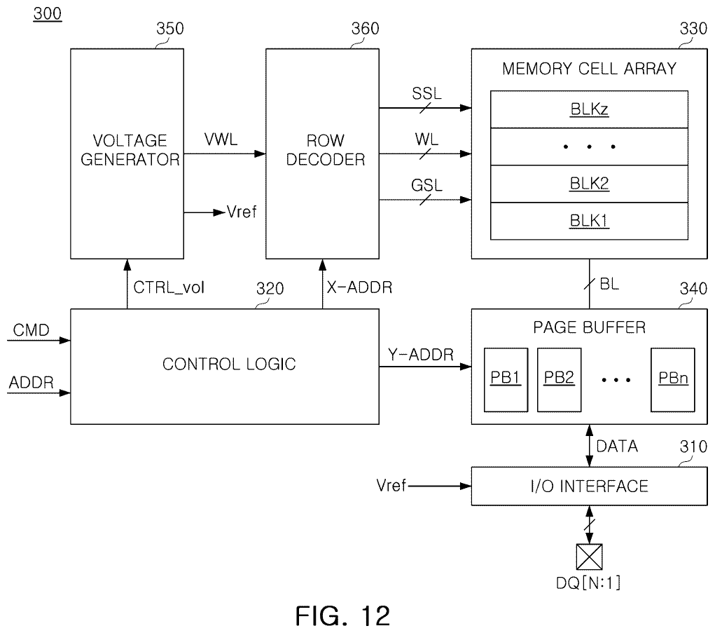

FIG. 11 is a graph illustrating voltage levels of signals while a reference voltage is calibrated according to some embodiments.

Specifically, FIG. 11 illustrates a voltage level of a reference voltage Vref, an intermediate voltage level Vcm, and a voltage level of an output signal Vout, over time.

In FIG. 11, an intermediate voltage formed by a pull-up driver and a pull-down driver may be referred to as an estimated intermediate voltage Vcm_est, and an intermediate voltage of a data signal DQ received from a data pin 210 may be referred to as a real intermediate voltage Vcm_real.

In an individual reference voltage calibration period illustrated in FIG. 11, a voltage level of an individual reference voltage Vref, a level of the estimated intermediate voltage Vcm_est, and a voltage level of an output signal Vout may be the same as the voltage level of the reference voltage Vref, the intermediate voltage level Vcm, and the output signal Vout, described with reference to FIG. 7B. For example, a data receiver 230 may adjust the voltage level of the reference voltage Vref based on the estimated intermediate voltage Vcm_est, until the voltage level of the output signal Vout is equal to a threshold level.

The estimated intermediate voltage Vcm_est may have an error from the real intermediate voltage Vcm_real. In an example of FIG. 11, the real intermediate voltage Vcm_real of the received data signal DQ after the reference voltage Vref is calibrated may be somewhat higher than the estimated intermediate voltage Vcm_est.

When there is a difference between the estimated intermediate voltage Vcm_est and the real intermediate voltage Vcm_real, it may be difficult that the reference voltage Vref calibrated by the estimated intermediate voltage Vcm_est provides a maximum effective window margin for the data signal DQ received from the data pin 210. For example, when the real intermediate voltage Vcm_real and the reference voltage Vref are applied to a data buffer 231, the output signal Vout may have a level voltage different from a target voltage level (0.5*VCCQ).

According to some embodiments, the reference voltages Vref may be collectively calibrated using data signals DQ[1] to DQ[N], to provide the maximum effective window margin for the data signal DQ. When the real intermediate voltage Vcm_real and the reference voltage Vref are applied to the data buffer 231, the reference voltage Vref may be calibrated such that the output signal Vout has the same voltage level as the target voltage level (0.5*VCCQ).

As described with reference to FIG. 1, the receiving device 200 may include a volatile memory device or a non-volatile memory device.

FIG. 12 is a view illustrating a memory device as an example of a receiving device according to some embodiments.

A memory device 300 of FIG. 12 may correspond to a receiving device 200, as described with reference to FIG. 1. Referring to FIG. 12, the memory device 300 may include an input/output interface circuit 310, a control logic circuit 320, a memory cell array 330, a page buffer 340, a voltage generator 350, and a row decoder 360. Although not illustrated in FIG. 12, the memory device 300 may further include a column logic, a pre-decoder, a temperature sensor, a command decoder, an address decoder, or the like.

The input/output interface circuit 310 may include a plurality of data receivers, as described with reference to FIGS. 1, 2, 3A, 3B, 4, 5, 6, 7A, 7B, 8A, 8B, 9, 10, and 11. Each of the plurality of data receivers may receive a data signal among a plurality of data signals DQ[N: 1], and may compare the data signal with a reference voltage Vref to output data DATA.

The control logic circuit 320 may generally control various operations in the memory device 300. The control logic circuit 320 may output various control signals in response to a command CMD and/or an address ADDR from the input/output interface circuit 310. For example, the control logic circuit 320 may output a voltage control signal CTRL_vol, a row address X-ADDR, and a column address Y-ADDR.

The memory cell array 330 may include a plurality of memory blocks BLK1 to BLKz (where z is a positive integer), and each of the plurality of memory blocks BLK1 to BLKz may include a plurality of memory cells. The memory cell array 330 may be connected to the page buffer 340 through bit lines BL, and may be connected to the row decoder 360 through word lines WL, string select lines SSL, and ground select lines GSL.

In example embodiments, the memory cell array 330 may include a 3D memory cell array, and the 3D memory cell array may include a plurality of NAND strings. Each of the NAND strings may include memory cells respectively connected to word lines stacked vertically on a substrate. U.S. Pat. Nos. 7,679,133, 8,553,466, 8,654,587, 8,559,235, and U.S. Patent Application Publication No. 2011/0233648 may be incorporated and combined herein by reference. In some embodiments, the memory cell array 330 may include a 2D memory cell array, and the 2D memory cell array may include a plurality of NAND strings, arranged in row and column directions. The page buffer 340 may include a plurality of page buffers PB1 to PBn (where n is an integer of 3 or more), and the plurality of page buffers PB1 to PBn may be connected to the memory cells through a plurality of bit lines BL. The page buffer 340 may select at least one bit line among the bit lines BL in response to the column address Y-ADDR. The page buffer 340 may operate as a write driver or a sense amplifier according to an operation mode. For example, during a programming operation, the page buffer 340 may apply a bit line voltage, corresponding to data to be programmed, to the selected bit line. During a read operation, the page buffer 340 may sense a current or a voltage of the selected bit line, to sense data stored in the memory cell.

The voltage generator 350 may generate various types of voltages for performing a programming operation, a read operation, and an erase operation, based on the voltage control signal CTRL_vol. For example, the voltage generator 350 may generate a program voltage, a read voltage, a program verification voltage, an erase voltage, and the like, and may generate the reference voltage Vref input to the input/output interface circuit 310.

The row decoder 360 may select one word line among the plurality of word lines WL in response to the row address X-ADDR, and may select one string select line among the plurality of string select lines SSL. For example, during the programming operation, the row decoder 360 may apply the program voltage and the program verification voltage to the selected word line, and may apply the read voltage to the selected word line during the read operation.

According to some embodiments, the input/output interface circuit 310 may individually adjust a voltage level of the reference voltage Vref input to the plurality of data receivers, to calibrate an offset of each of the plurality of data receivers.

Each of the plurality of data receivers may acquire an intermediate voltage level of the data signal by turning on a pull-up driver and a pull-down driver, in a state in which the data signal from a data pin is not received, and may use the intermediate voltage level to calibrate the voltage level of the reference voltage Vref. Therefore, the data receivers may calibrate the offset using the intermediate voltage level, regardless of whether the data receivers include a P-type data buffer or an N-type data buffer. Additionally, each of the plurality of data receivers may calibrate the offset without receiving external control.

According to some embodiments, after the calibration of the reference voltages Vref in each of the plurality of data receivers is completed, the input/output interface circuit 310 may collectively calibrate the voltages Vref using the data signals DQ[N:1], to provide a maximum effective window margin for the actually received data signals (DQ[N:1]).

The memory device 300 may support a function of individually adjusting the voltage level of the reference voltage Vref input to the plurality of data receivers in response to external control, according to specifications. The memory device 300 may include individual reference voltage control circuits for supporting the above functions. According to some embodiments, the memory device 300 may control the voltage level of the reference voltage Vref using the individual reference voltage control circuits, even when the plurality of data receivers adjust the voltage level of the reference voltage Vref without receiving external control.

A receiving device according to some embodiments may apply an intermediate voltage level of a data signal to data receivers without receiving the data signal externally and may calibrate a reference voltage according to a comparison result between the intermediate voltage level and the reference voltage, to directly calibrate an offset of the data receivers without receiving external control.

A receiving device according to some embodiments may adjust a reference voltage, instead of using an additional semiconductor element, to calibrate an offset of data receivers, thereby not placing an additional weight loading on an output terminal of the data receivers.

A receiving device according to some embodiments may calibrate a reference voltage according to a comparison result between the intermediate voltage level and the reference voltage, to calibrate an offset of data receivers regardless of whether the data receivers include a P-type data buffer or an N-type data buffer.

Problems to be solved by the present inventive concept are not limited to the problems mentioned above, and other problems not mentioned will be clearly understood by those skilled in the art from the description below.

While example embodiments have been illustrated and described above, it will be apparent to those skilled in the art that modifications and variations could be made without departing from the scope of the present inventive concept as defined by the appended claims.

What is claimed is:

1. A receiving device comprising:
a data pin;
a data buffer including a first input terminal configured to receive a data signal from the data pin, a second input terminal configured to receive a reference voltage, and an output terminal configured to output a comparison result between the data signal and the reference voltage as an output signal;
a driver electrically connected between the data pin and the first input terminal;
a reference voltage control circuit configured to output the reference voltage to the second input terminal, wherein the reference voltage corresponds to a reference voltage code; and
an adjustment circuit configured to apply an intermediate voltage of the data signal to the first input terminal using the driver, and configured to adjust the reference voltage code such that a voltage of the output signal reaches a target state.

2. The receiving device of claim 1, further comprising:
a latch circuit configured to store the reference voltage code that was adjusted and configured to provide the reference voltage code that was stored to the reference voltage control circuit.

3. The receiving device of claim 1, wherein the driver comprises:
a pull-up driver electrically connected between a power source and the first input terminal; and
a pull-down driver electrically connected between a ground and the first input terminal.

4. The receiving device of claim 3, wherein the adjustment circuit is configured to turn on both the pull-up driver and the pull-down driver and float the data pin, to apply the intermediate voltage to the first input terminal.

5. The receiving device of claim 4, further comprising:
a ZQ calibration circuit configured to generate a pull-up code and a pull-down code,
wherein the driver is configured to determine a pull-up resistance value by inputting the pull-up code into the pull-up driver, and configured to determine a pull-down resistance value by inputting the pull-down code into the pull-down driver.

6. The receiving device of claim 1, wherein the data buffer further comprises:
an amplifier configured to output a signal acquired by amplifying a difference between a voltage of a first output terminal and a voltage of a second output terminal as the output signal;
a first transistor comprising a gate that is electrically connected to the first input terminal and a drain that is electrically connected to the second output terminal;
a second transistor comprising a gate that is electrically connected to the second input terminal and a drain that is electrically connected to the first output terminal;
a third transistor configured to provide a bias current for the first transistor and the second transistor;
a first resistor that is electrically connected to the second output terminal; and
a second resistor that is electrically connected to the first output terminal.

7. The receiving device of claim 6, wherein the amplifier is configured to output the output signal having a power voltage, when the voltage of the first output terminal is greater than the voltage of the second output terminal, and configured to output the output signal having a ground voltage, when the voltage of the first output terminal is less than the voltage of the second output terminal, and
wherein the adjustment circuit is configured to adjust the reference voltage code until the output signal reaches the target state by toggling from the power voltage to the ground voltage, or toggling from the ground voltage to the power voltage.

8. The receiving device of claim 7, wherein the adjustment circuit is configured to increase the reference voltage code when the output signal has the power voltage, and is configured to decrease the reference voltage code when the output signal has the ground voltage.

9. The receiving device of claim 6, wherein the amplifier is configured to linearly amplify and output the difference between the voltage of the first output terminal and the voltage of the second output terminal, and configured to output the output signal having a medium voltage between a power voltage and a ground voltage when the voltage of the first output terminal is equal to the voltage of the second output terminal, and
wherein the adjustment circuit is configured to adjust the reference voltage code until the output signal reaches the target state at the medium voltage.

10. The receiving device of claim 9, wherein the adjustment circuit is configured to increase the reference voltage code when the output signal is greater than the medium voltage, and configured to decrease the reference voltage code when the output signal is less than the medium voltage.

11. The receiving device of claim 6, wherein the first, second, and third transistors are PMOS transistors,
wherein a source of the third transistor is electrically connected to a power source, and a drain of the third transistor is electrically connected to a source of the first transistor and a source of the second transistor,
wherein the first resistor is electrically connected between the drain of the first transistor and a ground, and
wherein the second resistor is electrically connected between the drain of the second transistor and the ground.

12. The receiving device of claim 6, wherein the first, second, and third transistors are NMOS transistors,
wherein a source of the third transistor is electrically connected to a ground, and a drain of the third transistor is electrically connected to a source of the first transistor and a source of the second transistor,
wherein the first resistor is electrically connected between the drain of the first transistor and a power source, and
wherein the second resistor is electrically connected between the drain of the second transistor and the power source.

13. A receiving device comprising:
a plurality of data pins;
a plurality of data receivers each including a data buffer that includes an input terminal configured to receive a respective data signal of a plurality of data signals from a respective data pin among the plurality of data pins, and configured to output a comparison result between the respective data signal and a respective reference voltage as an output signal, a driver electrically connected between the respective data pin and the respective input terminal, and an individual calibration circuit configured to adjust the respective reference voltage such that a voltage of the output signal reaches a target state when an estimated intermediate voltage of the data signal is applied to the respective input terminal; and
a group calibration circuit configured to adjust respective reference voltages of each of the plurality of data receivers, based on respective ones of a plurality of data signals input from respective ones of the plurality of data pins.

14. The receiving device of claim 13, wherein the driver of each of the plurality of data receivers comprises a respective pull-up driver and a respective pull-down driver, and
wherein the receiving device further comprises a ZQ calibration circuit configured to determine a driving capability of the respective pull-up driver and a driving capability of the respective pull-down driver of each of the plurality of data receivers.

15. The receiving device of claim 14, wherein the individual calibration circuit is configured to float the respective data pin and turn on the respective pull-up driver and the respective pull-down driver having the driving capability of the respective pull-up driver and the driving capability of the respective pull-down driver determined by the ZQ calibration circuit, to generate the estimated intermediate voltage.

16. The receiving device of claim 13, wherein the group calibration circuit is configured to receive the plurality of data signals after the respective reference voltages are adjusted in each of the plurality of data receivers, configured to find a common value maximizing an effective window margin of the plurality of data signals using the plurality of data signals, and configured to add or subtract the common value to the respective reference voltages of each of the plurality of data receivers, to adjust the respective reference voltages of each of the plurality of data receivers.

17. The receiving device of claim 13, further comprising at least one of a volatile memory device or a non-volatile memory device.

18. A receiving device comprising:
a data pin;
a data buffer including a first input terminal configured to receive a data signal from the data pin, a second input terminal configured to receive a reference voltage, and an output terminal configured to output a comparison result between the data signal and the reference voltage as an output signal; and
a reference voltage calibration circuit configured to apply an intermediate voltage of the data signal to the first input terminal, configured to initialize the reference voltage that is applied to the second input terminal, and configured to repeatedly perform adjusting the reference voltage until the output signal generated by comparing the intermediate voltage and the reference voltage reaches a target state.

19. The receiving device of claim 18, wherein the reference voltage calibration circuit is configured to store a reference voltage code corresponding to the reference voltage when the output signal reaches a threshold voltage in a latch circuit, and configured to input the reference voltage corresponding to the reference voltage code stored in the latch circuit to the data buffer, after the adjusting the reference voltage is completed.

20. The receiving device of claim 18, wherein the reference voltage calibration circuit is configured to set the reference voltage equal to the intermediate voltage to initialize the reference voltage.
